(19) United States
(12) Patent Application Publication
(10) Pub. No.: US 2024/0170571 A1
(43) Pub. Date: May 23, 2024

(54) SEMICONDUCTOR DEVICE

(71) Applicant: Renesas Electronics Corporation, Tokyo (JP)

(72) Inventors: Yoshinori HOSHINO, Tokyo (JP); Hiroya SHIMOYAMA, Tokyo (JP); Toshimune KANBARA, Tokyo (JP); Masataka NOMURA, Tokyo (JP)

(21) Appl. No.: 18/516,760

(22) Filed: Nov. 21, 2023

(30) Foreign Application Priority Data
Nov. 22, 2022 (JP) 2022-186083

(51) Int. Cl. H01L 29/78; H01L 29/06; H01L 29/40

(52) U.S. Cl. CPC H01L 29/7813; H01L 29/0696; H01L 29/407

(57) ABSTRACT

A semiconductor device includes a vertical MOSFET in which a trench including a gate electrode and a field plate electrode therebelow at a gate potential and a trench including a gate electrode and a field plate electrode therebelow at a source potential are alternately arranged on an upper surface of a semiconductor substrate in a plan view.

### CROSS-REFERENCE TO RELATED APPLICATIONS

The disclosure of Japanese Patent Application No. 2022-186083 filed on Nov. 22, 2022 including the specification, drawings and abstract is incorporated herein by reference in its entirety.

### BACKGROUND

The present invention relates to a semiconductor device, and particularly relates to an effective technology in application to a vertical MOSFET including a trench gate.

There are disclosed techniques listed below.
[Patent Document 1] Japanese Unexamined Patent Application Publication No. 2002-528916
[Patent Document 2] Japanese Unexamined Patent Application Publication No. 2011-199109

As a low-intermediate-voltage trench gate power MOSFET, it is known an in-trench double gate type power MOSFET in which a field plate electrode is included below a gate electrode (intrinsic gate electrode) in a trench. Patent Document 1 describes a vertical field effect transistor in which two polysilicon regions insulated from each other are formed in a trench. Here, the source potential is supplied to the lower polysilicon region. Patent Document 2 describes an in-trench double-gate type N-channel power MOSFET in which a linear trench gate electrode and a linear field plate electrode are embedded in a trench. Here, the gate potential is supplied to the lower field plate electrode.

### SUMMARY

In the in-trench double gate type power MOSFET, when the source potential is supplied to the field plate electrode, there is a problem that the on-resistance of the MOSFET increases as compared to the case where the gate potential is supplied thereto. That is, there is a problem in which a lower on-resistance of the element is achieved while maintaining the advantages (switching loss reduction, reduction of surge voltage, and false-on margin expansion) from supplying the source potential to the field plate electrode.

Other problems and novel features will become apparent from the description of the present specification and the accompanying drawings.

An outline of representative embodiments disclosed in the present application will be briefly described as follows.

A semiconductor device according to an embodiment includes a vertical MOSFET in which a trench including a gate electrode and a field plate electrode therebelow at a gate potential and a trench including a gate electrode and a field plate electrode therebelow at a source potential are alternately arranged in a plan view.

According to one embodiment, the performance of the semiconductor device can be improved.

### BRIEF DESCRIPTION OF THE DRAWINGS

FIG. 1 is a planar layout illustrating a semiconductor device according to an embodiment.

FIG. 2 is a cross-sectional view taken along line A-A in FIG. 1.

FIG. 3 is a cross-sectional view taken along line B-B in FIG. 1.

FIG. 4 is a cross-sectional view taken along line C-C in FIG. 1.

FIG. 5 is a cross-sectional view taken along line D-D in FIG. 1.

FIG. 6 is a planar layout illustrating a semiconductor device according to Modification 1 of the embodiment.

FIG. 7 is a cross-sectional view taken along line E-E in FIG. 6.

FIG. 8 is a cross-sectional view taken along line F-F in FIG. 6.

FIG. 9 is a planar layout illustrating a semiconductor device according to Modification 2 of the embodiment.

FIG. 10 is a cross-sectional view taken along line G-G in FIG. 9.

FIG. 11 is a planar layout illustrating a semiconductor device according to Modification 3 of the embodiment.

FIG. 12 is a cross-sectional view taken along line H-H in FIG. 11.

FIG. 13 is a cross-sectional view illustrating a semiconductor device according to Comparative Example 1.

FIG. 14 is a planar layout illustrating a semiconductor device according to Comparative Example 1.

FIG. 15 is a planar layout illustrating a semiconductor device according to Comparative Example 2.

### DETAILED DESCRIPTION

In the following embodiments, if it is necessary for the sake of convenience, the description will be divided into a plurality of sections or embodiments, but unless otherwise specified, the sections or embodiments are not unrelated to each other, and one is in a relationship of some or all modifications, details, supplementary explanation, and the like of the other. In addition, in the following embodiments, when referring to the number of elements and the like (including number, numerical value, amount, range, etc.), the number is not limited to the mentioned number, and may be equal to or more than the mentioned number or equal to or less than the mentioned number, unless otherwise specified or obviously limited in principle to a specific number.

Furthermore, in the following embodiments, it is obvious that the constituent elements (including element steps etc.) are not necessarily essential unless otherwise specified or considered to be obviously essential in principle. Similarly, in the following embodiments, when referring to the shape, positional relationship, and the like of the components and the like, it is assumed to include those substantially approximate or similar to the shape and the like unless otherwise specified or unless it is clearly considered otherwise in principle. The same applies to the above-mentioned numerical values and ranges.

Hereinafter, embodiments will be described in detail with reference to the drawings. Note that, in all the drawings for describing the embodiments, members having the same functions are denoted by the same reference numerals, and duplicated description thereof will be omitted. In addition, in the following embodiments, descriptions of the same or similar parts will not be repeated in principle unless particularly necessary.

In each plan view (planar layout) used in the following description, the contact plugs are hatched for the sake of easier understanding of the drawing.

Here, a power MOSFET (Metal Oxide Semiconductor Field Effect Transistor, MOS field effect transistor) will be described as an example of the semiconductor device of the present application. The power MOSFET is a semiconductor device that can handle power levels of several watts or more. The semiconductor device of the present application includes a trench gate power MOSFET among the power MOSFETs. The trench gate power MOSFET includes a gate electrode made of polysilicon or the like in a trench (relatively long narrow groove) formed on an upper surface (first main surface) of a semiconductor substrate, and a channel is formed in a thickness direction of the semiconductor substrate. In this case, normally, the upper surface side of the semiconductor substrate is a source, and the lower surface (back surface, second main surface) side is a drain.

In addition, the semiconductor device of the present application includes an in-trench double gate type power MOSFET among the trench gate power MOSFETs. The in-trench double gate type power MOSFET includes a field plate electrode below a gate electrode (intrinsic gate electrode) in a trench. When the field plate electrode is electrically connected to the source potential or the gate potential, the field plate electrode disperses a steep potential gradient concentrated in the vicinity of the drain-side end portion of the gate electrode, thereby keeping the electric field constant. By keeping the electric field in the vicinity of the field plate electrode constant, the withstand voltage of the element can be secured.

### Embodiment

### <Structure of Semiconductor Device>

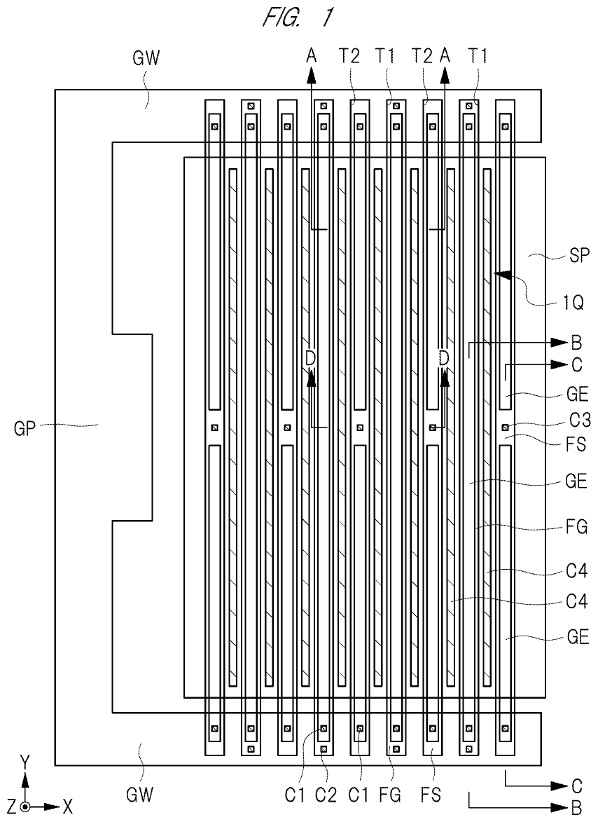

A semiconductor device according to the present embodiment will be described below with reference to FIGS. 1 to 5.

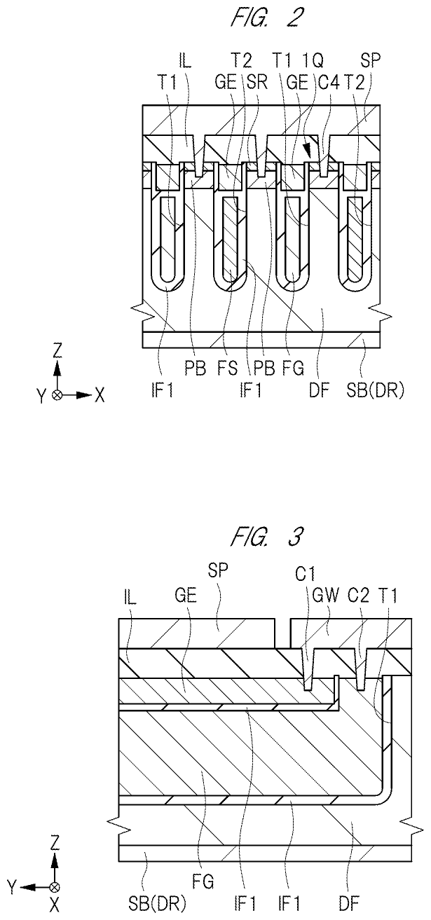

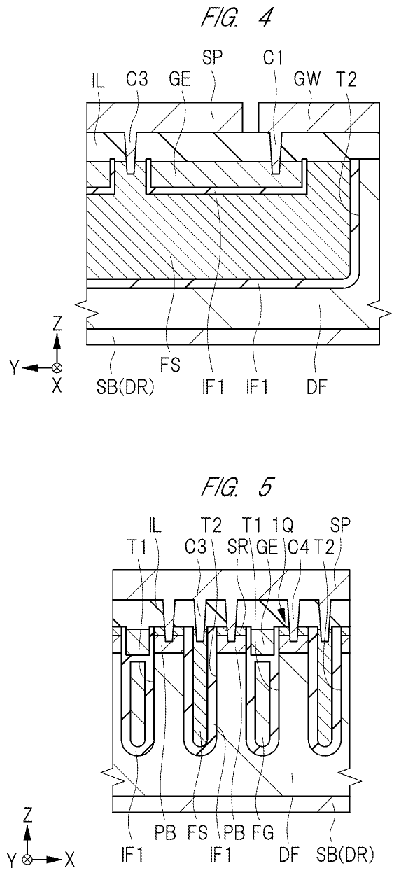

The semiconductor device of the present embodiment includes a semiconductor chip including a semiconductor substrate. As illustrated in FIG. 1, the semiconductor chip includes a plurality of MOSFETs 1Q arranged in the X-direction and connected in parallel with each other. In FIG. 1, the structure under the wiring formed on the upper surface of the semiconductor substrate is shown in a transparent manner, and illustrations of the semiconductor substrate and an insulating film such as an interlayer insulating film and a passivation film on the semiconductor substrate are omitted. FIG. 2 is a cross-sectional view taken along line A-A in FIG. 1. FIG. 3 is a cross-sectional view taken along line B-B in FIG. 1. FIG. 4 is a cross-sectional view taken along line C-C in FIG. 1. FIG. 5 is a cross-sectional view taken along line D-D in FIG. 1. The semiconductor substrate has an upper surface (first main surface) and a lower surface (back surface, second main surface) opposite to the upper surface.

As illustrated in FIG. 2, the semiconductor substrate as a component in the semiconductor device according to the present embodiment includes: a substrate SB, which is made of, for example, single crystal Si (silicon) or the like; and a drift layer DF, which is a semiconductor layer formed on the substrate SB by an epitaxial growth method or the like. The substrate SB includes an n⁺-type drain region DR. That is, the semiconductor substrate is a multilayer substrate in which the substrate SB and the drift layer (semiconductor layer) DF are included, and includes the drain region DR formed extending from the lower surface to a predetermined depth. That is, the drain region DR is formed between the lower surface of the semiconductor substrate and the drift layer DF. Although not illustrated, the lower surface of the substrate SB is covered with a drain electrode containing, for example, Au (gold), and the drain region DR is connected to the drain electrode. The drift layer DF is an n⁻-type semiconductor layer.

As illustrated in FIG. 1, a plurality of trenches T2 and a plurality of trenches T1 extending in a Y-direction are alternately formed in an X-direction on the upper surface of the semiconductor substrate. A MOSFET 1Q is formed in the vicinity of each of the trenches T1 and T2. The Y-direction and the X-direction are directions along the upper surface of the semiconductor substrate, and are directions orthogonal to each other in a plan view. A Z-direction that is orthogonal to each of the Y-direction and the X-direction is a height direction (thickness direction, vertical direction, or longitudinal direction) perpendicular to the upper surface of the semiconductor substrate.

As illustrated in FIGS. 2 to 5, a gate electrode (trench gate electrode) GE and a field plate electrode (trench gate electrode) FG under the gate electrode GE are formed inside the trench T1 via an insulating film IF1. In addition, the gate electrode GE and a field plate electrode (trench gate electrode) FS under the gate electrode GE are formed inside the trench T2 via the insulating film IF1. Herein, the structure in which the two electrodes are formed in the trench in this manner is referred to as a double gate structure (double gate type). The width of the field plate electrode in the lateral direction (X-direction) is smaller than the width of the gate electrode thereon in the lateral direction (X-direction). For this reason, in the X-direction, the thickness of the insulating film IF1 between each of the field plate electrodes FG and FS and the semiconductor substrate is larger than the thickness of the insulating film IF1 between the gate electrode GE and the semiconductor substrate. However, in FIG. 1, for the sale of easier understanding of the shape of the field plate electrode, the width of the field plate electrode is illustrated to be wider than the actual width.

In the trench T1, the gate electrode GE and the field plate electrode FG are spaced apart from each other with the insulating film IF1 interposed therebetween. In the trench T2, the gate electrode GE and the field plate electrode FS are spaced apart from each with the insulating film IF1 interposed therebetween. The field plate electrodes FG and FS are located on the lower surface side of the semiconductor substrate with respect to the gate electrode GE. Each of the gate electrode GE, the field plate electrodes FS, and FG is made of, for example, polysilicon.

In the semiconductor substrate, a body layer PB which is a p-type semiconductor layer is formed in contact with both side surfaces of the trenches T1 and T2, and extending from the upper surface of the semiconductor substrate (the upper surface of a drift layer DF) to a predetermined depth. That is, the body layer PB is formed between the upper surface of the semiconductor substrate and the drift layer DF. The depth of the body layer PB is shallower than the depth of any of the trenches T1 and T2 and the gate electrode GE, for example. In other words, the trenches T1 and T2 penetrate the body layer PB.

In addition, in the semiconductor substrate, a source region SR, which is an n⁺-type semiconductor region (n⁺ diffusion layer), is formed in contact with the side surfaces of each of the trenches T1 and T2, and extending from the upper surface (upper surface of the drift layer DF, upper surface of the body layer PB) of the semiconductor substrate to a predetermined depth. The source region SR is in contact with the upper surface of the semiconductor substrate. The depth of the source region SR is shallower than the depth of any of the body layer PB and the gate electrode GE. That is, the source region SR is formed between the upper surface of the semiconductor substrate and the body layer PB. The lower surface of the source region SR is in contact with the body layer PB, and the lower surface of the body layer PB is in contact with the drift layer DF. The trenches T1 and T2 penetrate the source region SR and the body layer PB and extend to the drift layer DF.

The source region SR, the drain region DR, the body layer PB, and the gate electrode GE are components in an n-type MOSFET 1Q which is a vertical MOSFET.

As illustrated in FIGS. 1 to 5, a metal film (conductive film, source wiring) as a component in a source pad SP and a gate wiring GW are formed on the semiconductor substrate, the gate electrode GE, the insulating film IF1, and the field plate electrodes FG and FS with an interlayer insulating film IL interposed therebetween. The interlayer insulating film IL is mainly made of, for example, silicon oxide. The metal film (conductive film, source wiring) as a component in the source pad SP and the gate wiring GW are made of, for example, Al (aluminum), are located at the same height, and are separated from each other.

A plurality of openings (through-hole, contact hole) is formed in the interlayer insulating film IL. In these openings, a metal film (source wiring) as a component in the source pad SP, or a contact plug (conductive connection portion) integrated with the gate wiring GW is formed. Hereinafter, strictly speaking, the source pad SP refers to a portion exposed from an insulating film (not illustrated) such as a passivation film in the upper surface of the metal film (source wiring), but hereinafter, this metal film is referred to as the source pad SP.

The trenches T1 and T2, the gate electrode GE, the field plate electrodes FG and FS, and a contact plug C4 extend in the Y-direction. However, immediately below the central portion of the source pad SP in the Y-direction, the gate electrode GE in the trench T2 is separated into two, and a contact plug C3 is connected to the field plate electrode FS in between the two gate electrodes GE adjacent to each other in the Y-direction.

A portion of the gate wiring GW is formed adjacent to the outside of the source pad SP in the Y-direction and extends in the X-direction. The other portion of the gate wiring GW is adjacent to the source pad SP in the X-direction. The gate wiring GW is electrically connected to the gate electrode GE inside each of the trenches T1 and T2 via a contact plug C1. A portion of the upper surface of the gate wiring GW is included in a gate pad GP, and a gate potential is supplied to the gate electrode GE via the gate pad GP, the gate wiring GW, and the contact plug C1. The contact plug C1 is formed immediately above the end portion of the gate electrode GE in the Y-direction.

The gate wiring GW is electrically connected to the field plate electrode FG in the trench T1 via a contact plug C2. The contact plug C2 is formed immediately above the end portion of the field plate electrode FG in the Y-direction. In the vicinity of the formation region of the contact plug C2, the gate electrode GE is not formed in the trench T2. In other words, in the region where the contact plug C2 is connected to the upper surface of the field plate electrode FG, the upper surface of the field plate electrode FG is exposed from the gate electrode GE. That is, the field plate electrode FG is embedded extending from the vicinity of the lower end to the vicinity of the upper end of the trench T2 in the trench T2 in the vicinity of the formation region of the contact plug C2. A gate potential is supplied to the field plate electrode FG via the gate pad GP, the gate wiring GW, and the contact plug C2.

The source pad SP is electrically connected to the field plate electrode FS in the trench T2 via the contact plug C3. The contact plug C3 is formed immediately above the central portion of the field plate electrode FS in the Y-direction. The gate electrode GE is not formed in the trench T2 in the vicinity of the formation region (power supply unit) of the contact plug C3. In other words, in the region where the contact plug C3 is connected to the upper surface of the field plate electrode FS, the upper surface of the field plate electrode FS is exposed from the gate electrode GE. That is, the field plate electrode FS is embedded from the vicinity of the lower end to the vicinity of the upper end of the trench T2 in the trench T2 in the vicinity of the formation region of the contact plug C3. A source potential is supplied to the field plate electrode FS via the source pad SP and the contact plug C3.

The source pad SP is electrically connected to the source region SR and the body layer PB via the contact plug C4. The contact plug C4 extends along the extending direction (Y-direction) of the trenches T1 and T2. The contact plug C4 extends to an intermediate depth in the body layer PB, which is a position deeper than the source region SR, and is in contact with the source region SR. In order to reduce the connection resistance between the contact plug C4 and the body layer PB, a p-type semiconductor region having a higher concentration than that in the body layer PB may be formed in the semiconductor substrate therebetween. A source potential is supplied to the source region SR and the body layer PB via the source pad SP and the contact plug C4.

FIG. 5 illustrates a cross section along the X-direction and including the contact plug C3. As illustrated in FIG. 5, the contact plug C3 whose width in the lateral direction is smaller than a width of the trench 12 in the lateral direction is connected to the field plate electrode FS embedded in the trench T2. The contact plug C3 extends to an intermediate depth below the upper surface of the field plate electrode FS (toward the lower surface side of the semiconductor substrate). Although not illustrated, a titanium silicide layer configured to reduce the connection resistance is formed between the contact plug C3 and the field plate electrode FS. The bottom surface of the contact plug C3 connected to or integrated with the source pad SP is connected to the upper surface of the field plate electrode FS at the same height as the uppermost t surface of the semiconductor substrate or below the uppermost surface of the semiconductor substrate (at a height on the lower surface side of the semiconductor substrate).

The configuration set forth above also applies to the contact plug C2 connected to the field plate electrode FG embedded in the trench T1 in the region not illustrated in FIG. 5. That is, each of the contact plugs C2 and C3 is directly connected to the field plate electrodes FS and FG via a silicide layer. Each of the contact plugs C1 to C2 has a width in the lateral direction smaller than a width of the trenches T1 and T2 in the lateral direction. Further, the bottom surface of each of the contact plugs C1 to C3 is connected to the upper surface of the field plate electrode FS at the same height as the uppermost surface of the semiconductor substrate or below the uppermost surface of the semiconductor substrate (at a height on the lower surface side of the semiconductor substrate). However, when a portion of the field plate electrodes FG and FS or of the gate electrode GE is formed above the uppermost surface of the semiconductor substrate, the bottom surfaces of the contact plugs C1 to C3 can be connected to the field plate electrodes FG and FS or the gate electrode GE at a height above the uppermost surface of the semiconductor substrate.

Here, the operation of the MOSFET will be described. When a MOSFET 1Q is in on-state, a channel (inversion layer) is formed in the body layer PB adjacent to the trenches T1 and T2 in which the gate electrode GE is provided, and a current flows from a drain region DR to the source region SR through the drift layer DF and the channel in the body layer PB.

Each MOSFET of the present embodiment is an in-trench double gate type power MOSFET, and has a field plate electrode in the trench, to which a source potential is applied, so that parasitic capacitance of the MOSFET can be reduced and a switching speed of the MOSFET can be increased.

One of the main features of the semiconductor device of the present embodiment is that a gate electrode and a field plate electrode are embedded in each of trenches formed side by side on a semiconductor substrate, and a field plate electrode to which a source potential is applied and a field plate electrode to which a gate potential is applied are mixedly mounted.

### Effects of Present Embodiment

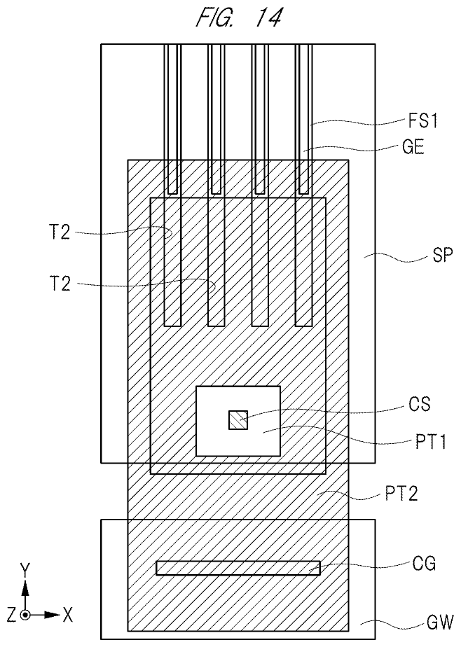

FIG. 13 is a cross-sectional view of a semiconductor device which is Comparative Example 1. The semiconductor device of the comparative example includes an n-type MOSFET 2Q which is a vertical MOSFET. The structure of the MOSFET illustrated in FIG. 13 is different from that of the semiconductor device illustrated in FIG. 2 in that only a plurality of trenches T2 is arranged in the X-direction, and all the field plate electrodes FS1 in the trenches T2 in the active region (element region) are electrodes to which a source potential is applied.

As described above, in an element (source field plate type element) in which the potentials of all the field plate electrodes FS1 are configured to be the source potential, both a gate-drain charge amount Qgd and a feedback capacitance Crss are lower than those of an element (gate field plate type element) in which the gate potential is applied to all the field plate electrodes. For this reason, the switching loss is reduced, and it is advantageous for expanding the false-on margin. In addition, the source field plate type element has a parasitic built-in snubber between the drain and the source, and is characterized in that a recovery surge is hardly generated. On the other hand, the source field plate type element is disadvantageous in that the on-resistance Ron is higher than that in the gate field plate type element.

The semiconductor device of the present embodiment has a structure including both a source field plate and a gate field plate at the same time. This makes it possible to reduce the on-resistance as in the gate field plate type element while maintaining the merit (switching loss reduction, and false-on margin expansion) of the source field plate type element.

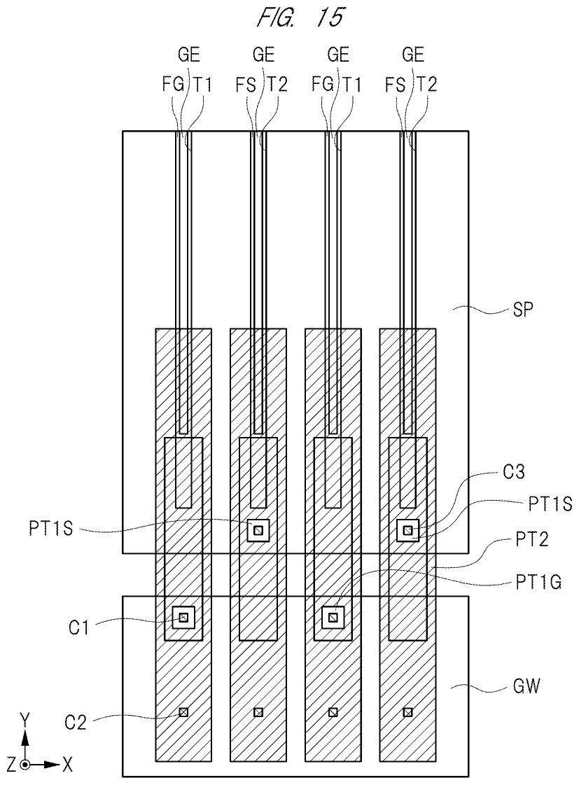

Here, a planar layout of the power supply unit to the gate electrode and the field plate electrode of the semiconductor device of Comparative Example 1 is illustrated in FIG. 14. In Comparative Example 1, there is employed a structure in which each of the field plate electrode FS1 and the gate electrode GE is drawn out to conductive patterns PT1 and PT2 on the upper surface of the semiconductor substrate, and the patterns PT1 and PT2 and the source pad SP or the gate wiring GW are connected by contact plugs CS and CG. That is, the source pad SP is electrically connected to a field plate electrode FS1 via the contact plug CS and the pattern PT1. The gate wiring GW is electrically connected to the gate electrode GE via the contact plug CG and the pattern PT2.

In FIG. 14, the pattern PT2 electrically connected to the gate wiring GW and the gate electrode GE is hatched, and the pattern PT1 or the like under the pattern PT2 is illustrated in a transparent manner. Although the width of the field plate electrode FS1 in the lateral direction (X-direction) is smaller than the width of the gate electrode GE thereon in the lateral direction, the field plate electrode FS1 is illustrated with a width larger than the width of the gate electrode GE in FIG. 12 for the sake of easier understanding of the drawing as in FIG. 1. In Comparative Example 1, the source potential is supplied to the field plate electrode FS1 with the aid of the pattern PT1 extending so as to overlap the field plate electrode FS1 in the plurality of trenches T2 arranged in the X-direction in a plan view.

The pattern PT1 is a portion where a part of the field plate electrode FS1 lies on top of the upper surface of the semiconductor substrate, and the pattern PT1 and the field plate electrode FS1 are united. In addition, the pattern PT2 is a portion where a part of the gate electrode GE lies on top of the upper surface of the semiconductor substrate, and a part of the pattern PT2 lies on top of the pattern PT1. That is, the pattern PT2 and the gate electrode GE are united.

As in the present embodiment, in case of offering advantages of both the source field plate type and the gate field plate type elements, the most balanced is a manner of alternately arranging the field plate electrode at the source potential and the field plate electrode at the gate potential. However, in an attempt to supply the source potential and the gate potential to the field plate electrode via the conductive pattern on the semiconductor substrate as in Comparative Example 1 illustrated in FIG. 14, there arises a problem in which the placement period of the trenches increases as in Comparative Example 2 illustrated in FIG. 15. Concerning this point, there will be specifically described below.

FIG. 15 is a planar layout illustrating a power supply unit to a gate electrode and a field plate electrode of a semiconductor device of Comparative Example 2. In Comparative Example 2, similarly to Comparative Example 1 illustrated in FIG. 14, a source potential is supplied to the field plate electrode FS via a pattern PT1S. In addition, here, the gate potential is supplied to the field plate electrode FG via a pattern PT1G adjacent to the pattern PT1S. In FIG. 15, the pattern PT2 electrically connected to the gate wiring GW is hatched, and the patterns PT1S, PT1G, and the like under the pattern PT2 are illustrated in a transparent manner.

The pattern PT1S is a portion where a part of the field plate electrode FS lies on top of the upper surface of the semiconductor substrate, and the pattern PT1S and the field plate electrode FS are united. The pattern PT1G is a portion where a part of the field plate electrode FG lies on top of the upper surface of the semiconductor substrate, and the pattern PT1G and the field plate electrode FG are united. In addition, the pattern PT2 is a portion where a part of the gate electrode GE lies on top of the semiconductor substrate, and a part of the pattern PT2 lies on top of the pattern PT1S or PT1G. That is, the pattern PT2 and the gate electrode GE are united. The source pad SP is electrically connected to the pattern PT1S via the contact plug C3, and the gate wiring GW is electrically connected to the pattern PT1G via the contact plug C1. The gate wiring GW is electrically connected to the pattern PT2 via the contact plug C2.

In the active region, trenches T1 and T2 are alternately arranged in the X-direction. That is, the field plate electrode FS at the source potential and the field plate electrode FG at the gate potential are alternately arranged. For this reason, the pattern PT1G formed immediately above the trench T1 and the pattern PT1S formed immediately above the trench T2 are alternately arranged in the X-direction. In this case, the placement period of the patterns PT1S and PT1G increases. Therefore, there arises a problem of an increased cell pitch compared to Comparative Example 1 and an increased area of the semiconductor device.

On the other hand, in the present embodiment, as illustrated in FIGS. 2 to 5, each of the contact plugs C2 and C3 connected to the pad is directly connected to the field plate electrodes FS and FG via a silicide layer (not illustrated) not via the pattern on the semiconductor substrate as described above. Here, the contact plugs C2 and C3 having a width in the lateral direction smaller than the width of the trenches T1 and T2 in the lateral direction are connected to each of the field plate electrodes FG and FS. For this reason, there can be prevented an increase in the placement period (pitch) between the trenches T1 and T2 due to alternate arrangement of the field plate electrode FS at the source potential and the field plate electrode FG at the gate potential, as in Comparative Example 2 illustrated in FIG. 15. That is, an increase in the cell pitch can be prevented.

There has been provided the description of (GS alternate arrangement) in which the field plate electrodes FS and FG are alternately arranged one by one, however, the arrangement ratio of the field plate electrodes FS and FG is not limited thereto in the present embodiment. For example, the arrangement ratio may be altered such as a structure in which the field plate electrodes FG, FG, and FS are arranged in this order in the X-direction (GGS arrangement) or a structure in which the field plate electrodes FG, FS, and FS are arranged in this order (GSS arrangement). By altering the arrangement ratio of the field plate electrodes of the gate potential and the source potential, characteristics can be tuned according to the application of the element. For example, it is conceivable that the GGS arrangement is adapted when emphasis is placed on reducing the on-resistance, and the GSS arrangement is adapted when emphasis is placed on reducing the switching loss.

As described above, the performance of the semiconductor device can be improved according to the present embodiment.

In addition, as another problem, there are cases where a built-in resistor (gate resistor) connected to the gate is mounted in order to improve uniform performance of the element when the MOSFETs are connected in parallel. However, for example, a method in which a pattern made of a polysilicon film is formed on a semiconductor substrate and this pattern is used as a built-in resistor is disadvantageous in that an increase in process cost due to the addition of a process and a decrease in active area due to the formation of the built-in resistor. In contrast, in the present embodiment, the field plate electrode FG at the gate potential is used also as a built-in resistor, so that the built-in resistor can be mounted without adding a process and suppressing a decrease in area.

### <Modification 1>

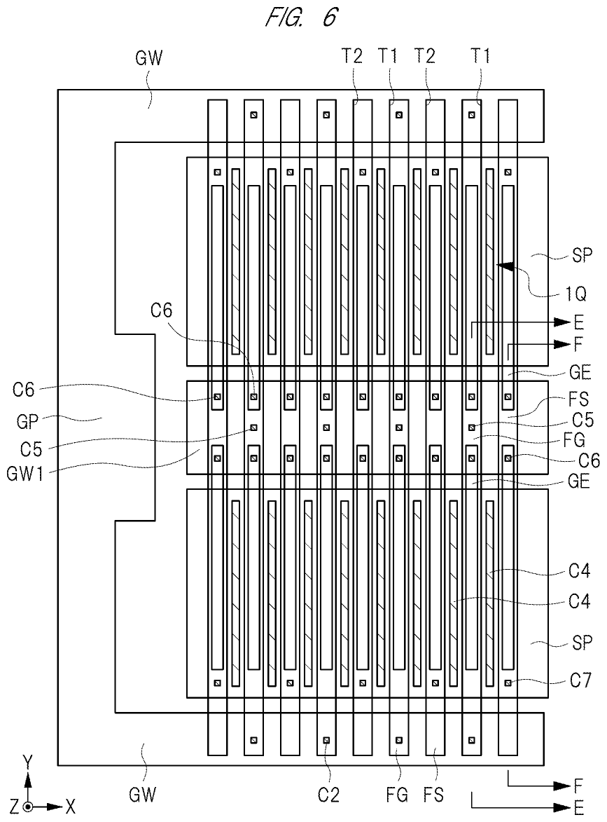

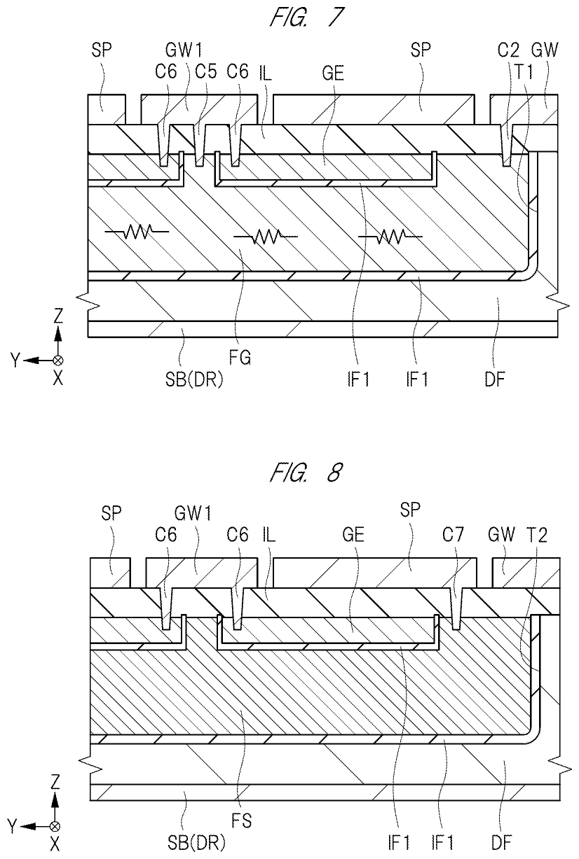

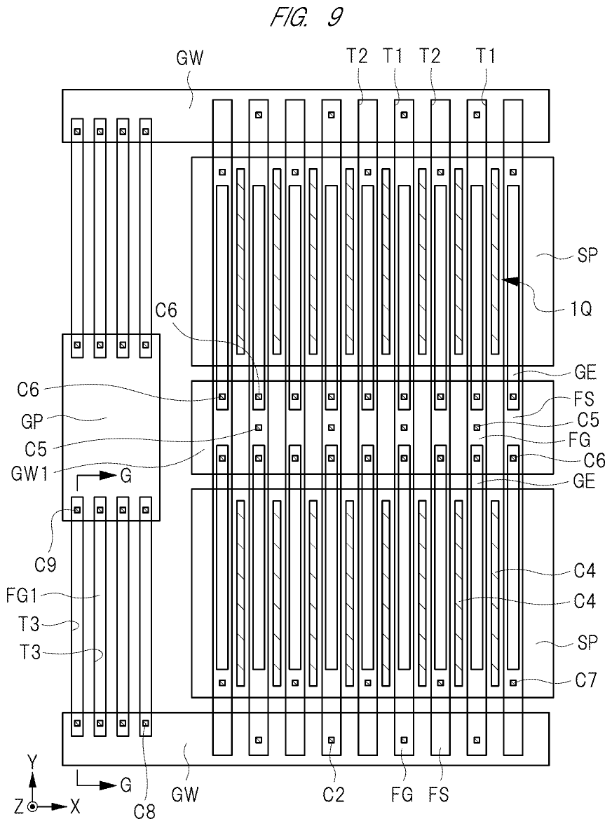

FIGS. 6 to 8 illustrate a modification in a case where a field plate at a gate potential is used also as a built-in resistor based on the structure of FIG. 1. FIG. 6 is a planar layout illustrating a semiconductor device of the present modification. FIG. 7 is a cross-sectional view taken along line E-E in FIG. 6. FIG. 8 is a cross-sectional view taken along line F-F in FIG. 6.

As illustrated in FIGS. 6 to 8, in the present modification, the source pad SP is divided into two in the Y-direction, and the gate wiring GW1 for raising the gate potential is provided between the source pads SP.

The trenches T1 and T2, the gate electrode GE, the field plate electrodes FG and FS, and a contact plug C4 extend in the Y-direction. However, the contact plug C4 and all the gate electrodes GE are separated into two at immediately below the gate wiring GW1. A contact plug C5 is connected to the upper surface of the field plate electrode FG in between two of the gate electrodes GE adjacent to each other in the Y-direction in the trench T1. A contact plug C6 disposed immediately below the gate wiring GW1 and united with the gate wiring GW1 is connected to the upper surface of the gate electrode GE inside each of the trenches T1 and T2. The field plate electrode FG is connected at one end portion in the Y-direction to the contact plug C2 immediately below the gate wiring GW.

That is, a gate potential is applied to the field plate electrode FG from the gate pad GP via the gate wiring GW and the contact plug C2. A gate potential is applied to the gate electrode GE from the field plate electrode FG via the contact plug C6, the gate wiring GW1, and the contact plug C5. Here, the gate electrode GE of the MOSFET 1Q is connected to the gate pad GP via the resistance of the field plate electrode FG embedded in the stripe-shaped trench T1. As a result, the field plate electrode FG serves as a built-in resistor (gate resistor).

A source potential is supplied to the field plate electrode FS via a contact plug C7 immediately below the source pad SP.

In the present modification, there can be obtained effects similar to those of the embodiment described with reference to FIG. 1. Furthermore, when a built-in resistor is desired to be added to the present embodiment, the field plate electrode FG at the gate potential is utilized also as a built-in resistor, whereby the built-in resistor can be mounted without adding a process and suppressing a decrease in area.

### <Modification 2>

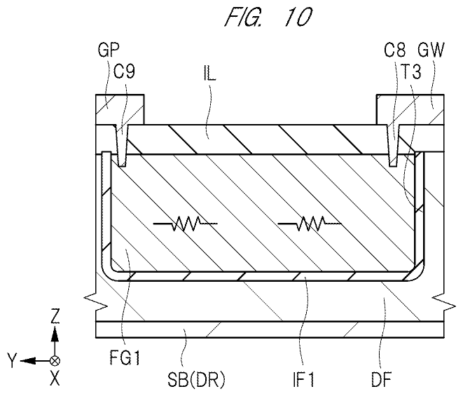

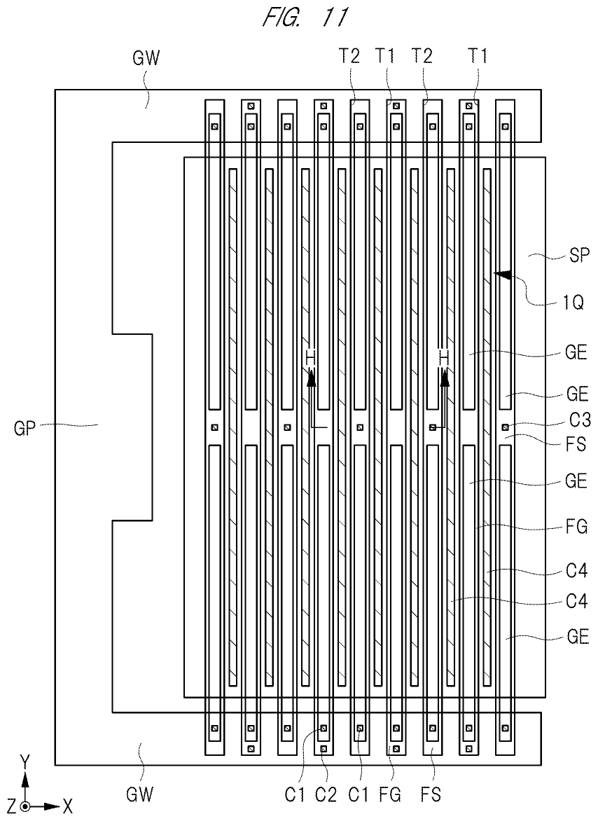

As illustrated in FIGS. 9 and 10, the field plate electrode FG1 may be formed in the trench T3 so as to make a connection between the gate wiring GW and the gate pad GP. FIG. 9 is a planar layout illustrating a semiconductor device of the present modification. FIG. 10 is a cross-sectional view taken along line G-G in FIG. 9. The configuration of the active region where the MOSFET 1Q is formed is similar to that of Modification 1.

The present modification is an example in which the resistance value of the built-in resistor is further increased as compared to Modification 1. Here, the trench T3 is formed extending from immediately below the gate pad GP to immediately below the gate wiring GW on the upper surface of the semiconductor substrate. The trench T3 extends in the Y-direction and the plurality thereof is arranged in the X-direction. In the trench T3, a field plate electrode FG1 is formed with the insulating film IF1 interposed therebetween. The gate wiring GW is connected to an upper surface of one end portion of the field plate electrode FG1 in the Y-direction with the aid of a contact plug C8 formed at immediately below the gate wiring GW and united with the gate wiring GW. The gate pad GP is connected to the upper surface of the other end portion of the field plate electrode FG1 in the Y-direction with the aid of a contact plug C9 formed immediately below the gate pad GP and united with the gate pad GP. The configuration of each of the contact plugs C8 and C9 are similar to that of the contact plug C2, for example.

In this manner, the gate pad GP and the gate wiring GW are electrically connected via the field plate electrode FG1. A gate potential is applied to the gate electrode GE via the gate pad GP, the contact plug C9, the field plate electrode FG1, the contact plug C8, the gate wiring GW, the contact plug C2, the field plate electrode FG, the contact plug C5, the gate wiring GW1, and the contact plug C6 in this order. Since the field plate electrode FG1 can be used as a built-in resistor, in the present modification, the built-in resistance can be further increased as compared to Modification 1. For this reason, when the MOSFETs are connected in parallel, there can be obtained an effect of facilitating uniform performance in each MOSFET.

### <Modification 3>

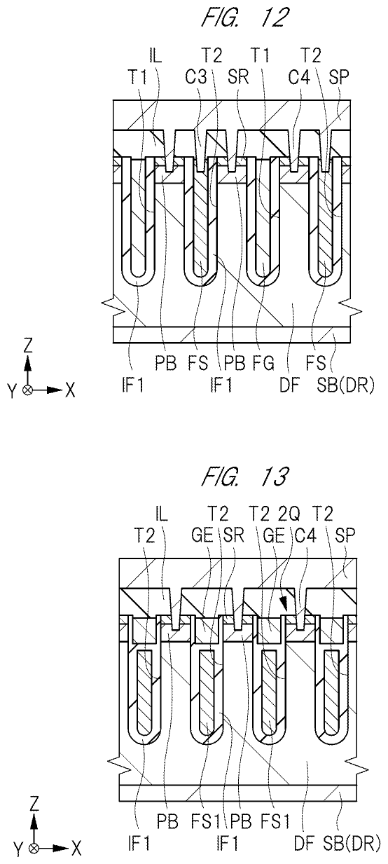

As illustrated in FIGS. 11 and 12, the gate electrode GE extending in the Y-direction may be divided without forming the gate electrode GE immediately above the field plate electrode FG at a position adjacent to the power supply unit to the field plate electrode FS in the X-direction. FIG. 12 is a cross-sectional view taken along line H-H in FIG. 11. The configuration other than the layout of the gate electrode GE is similar to that of the embodiment described with reference to FIGS. 1 to 5.

As illustrated in FIG. 11, the contact plug C3 formed immediately below the central portion of the field plate electrode FS in the Y-direction is connected to the field plate electrode FS. In the vicinity of the formation region (power supply unit) of the contact plug C3, the gate electrode GE is not formed in the trench T2. In addition, the gate electrode GE is not formed immediately above the field plate electrode FG at a position adjacent to the power supply unit to the field plate electrode FS in the X-direction. That is, the gate electrode GE extending in the Y-direction is divided.

As illustrated in FIGS. 1 and 5, there may be a case where it is difficult for photolithography technology to form the gate electrode GE so as to extend immediately above the field plate electrode FG at a position adjacent to the power supply unit in the X-direction while the gate electrode GE is not formed in the power supply unit to the field plate electrode FS. In such a case, as in the present modification, the gate electrode GE can be divided at a position adjacent to the power supply unit in the X-direction in accordance with the shape of the gate electrode GE of the power supply unit to the field plate electrode FS. Even in such a case, the same effects as those of the embodiment described with reference to FIGS. 1 to 5 can be obtained.

The invention made by the present inventors has been specifically described based on the embodiments, however, the present invention is not limited to the above-described embodiments, and it is obvious that various modifications can be made without departing from the gist of the present invention.

For example, the polarities of the components of the MOSFET described in the embodiment set forth above may be reversed. That is, the MOSFET may be a p-type MOSFET.

What is claimed is:

1. A semiconductor device comprising:
a semiconductor substrate having a first main surface and a second main surface opposite to the first main surface;
a first semiconductor region of a first conductivity type, formed in the semiconductor substrate;
a second semiconductor region of the first conductivity type, formed in the semiconductor substrate between the second main surface of the semiconductor substrate and the first semiconductor region;
a third semiconductor region of a second conductivity type different from the first conductivity type, the third semiconductor region being formed in the semiconductor substrate between the first main surface and the first semiconductor region;
a fourth semiconductor region of the first conductivity type, formed in the semiconductor substrate between the first main surface and the third semiconductor region;
a plurality of first trenches formed extending from the first main surface to an intermediate depth of the semiconductor substrate, extending in a first direction along the first main surface of the semiconductor substrate, and arranged in a second direction orthogonal to the first direction in a plan view;
a gate electrode formed inside each of the plurality of first trenches with an insulating film interposed therebetween and adjacent to the third semiconductor region in the second direction;
a first electrode formed in the first trench with the insulating film interposed therebetween and formed on the second main surface side with respect to the gate electrode with spaced apart from the gate electrode;
a second electrode formed in another of the first trenches adjacent to the first trench including the first electrode with the insulating film interposed therebetween and formed on the second main surface side with respect to the gate electrode with spaced apart from the gate electrode; and
a plurality of conductive connection portions connected to each of the gate electrode, the first electrode, and the second electrode,
wherein the plurality of first trenches penetrates the third semiconductor region and the fourth semiconductor region and extends to the first semiconductor region,
wherein a gate potential is applied to the gate electrode and the first electrode, and
wherein a source potential is applied to the fourth semiconductor region, the third semiconductor region, and the second electrode.

2. The semiconductor device according to claim 1,
wherein the first electrode and the second electrode are alternately arranged in the second direction.

3. The semiconductor device according to claim 1,
wherein a width of the conductive connection portion is smaller than a width of the first trench in the second direction.

4. The semiconductor device according to claim 1,
wherein in a region where the conductive connection portion is connected to an upper surface of the first electrode and a region where the conductive connection portion is connected to an upper surface of the second electrode, the upper surface of each of the first electrode and the second electrode is exposed from the gate electrode.

5. The semiconductor device according to claim 1,
wherein a gate potential is applied to the gate electrode via the first electrode.

6. The semiconductor device according to claim 5,
wherein the first electrode is used as a built-in resistor.

7. The semiconductor device according to claim 1, further comprising:
a second trench formed extending from the first main surface to an intermediate depth of the semiconductor substrate; and
a third electrode formed in the second trench with the insulating film interposed therebetween,
wherein a gate potential is applied to the gate electrode via the third electrode.

8. The semiconductor device according to claim 7, further comprising:
a gate pad formed on the first main surface; and
a gate wiring formed on the first main surface,
wherein a gate potential is applied to the gate electrode via the gate pad, the third electrode, and the gate wiring in this order.

9. The semiconductor device according to claim 8,
wherein the third electrode is used as a built-in resistor.

10. The semiconductor device according to claim 8,
wherein a gate potential is applied to the gate electrode via the gate pad, the third electrode, the gate wiring, and the first electrode in this order.

11. The semiconductor device according to claim 10,
wherein the first electrode and the third electrode each are used as a built-in resistor.
